(19) United States
(12) Patent Application Publication
(10) Pub. No.: US 2023/0228498 A1
(43) Pub. Date: Jul. 20, 2023

(54) TIGHT-FIT RIVETING STRUCTURE FOR HEAT DISSIPATION ALUMINUM BASE AND HEAT PIPE

(71) Applicant: Dongguan Hanxu Hardware Plastic Technology Co., Ltd., Dongguan (CN)

(72) Inventor: Tsung-Hsien Huang, Dongguan (CN)

(21) Appl. No.: 17/730,177

(22) Filed: Apr. 26, 2022

(30) Foreign Application Priority Data
Jan. 14, 2022 (CN) 202210044274.5

(51) Int. Cl. F28D 15/02; H05K 7/20

(52) U.S. Cl. CPC F28D 15/0275; H05K 7/20336; H05K 7/2039

(57) ABSTRACT

A tight-fit riveting structure for a heat dissipation aluminum base and a heat pipe includes a heat dissipation aluminum base, a heat pipe, and a holder. When the heat dissipation aluminum base is to be manufactured, an upper surface of a thin aluminum plate is pressed downward to form an arched portion. The arched portion protrudes below the thin aluminum plate. A cavity is defined in the arched portion. The cavity has an upper end opening. The cavity has an inner width corresponding to an outer width of the heat pipe. The cavity has a depth greater than a thickness of the heat pipe.

### BACKGROUND OF THE INVENTION

### 1. Field of the Invention

The present invention relates to a heat dissipation device, and more particularly to a tight-fit riveting structure for a heat dissipation aluminum base and a heat pipe.

### 2. Description of the Prior Art

There are various portable electronic devices on the market, such as a mobile phone, laptop, tablet computer, MP3 player, MP4 player, iPad, personal digital assistant (PDA), global position system (GPS) and so on. Due to the rapid advancement of technology, the volume and appearance of the portable electronic devices have become thinner and lighter. However, the computing function is becoming more and more powerful, so the central processing unit (CPU) and integrated circuit (IC) or other heat-generating unit inside the portable electronic device will generate high-temperature heat in operation. Therefore, it is necessary to radiate the high-temperature heat, so as to ensure the normal operation of the heat-generating unit and maintain its service life.

Chinese Utility Model Publication No. CN 202285480 U discloses a combined structure of a heat dissipation base plate and a heat pipe. The size of the accommodating groove of the heat dissipation base plate is obviously greater than that of the heat pipe in the initial state, and the thickness of the heat pipe is obviously greater than the depth of the accommodating groove. After the heat pipe is placed in the accommodating groove, the rib and the heat pipe are riveted by a mechanical riveting and flattening process. Although the heat pipe is squeezed and deformed, its thickness will be reduced to match the depth of the accommodating groove, and the size of the heat pipe will become larger after being squeezed and deformed. The theoretical ideal state of the processing design is that the size of the heat pipe after being squeezed and deformed corresponds to the inner size of the accommodating groove. In fact, subject to the accuracy of material deformation and uncontrollable factors, there will be a gap between the heat pipe and the accommodating groove. This leads to insufficient tightness and connection between the heat pipe and the heat dissipation base plate, which directly affects the heat transfer efficiency. Although this document also discloses that a heat-conducting medium, such as heat-conducting paste, is disposed on the two side walls and the bottom of the accommodating groove. When the heat pipe is squeezed and deformed, the heat-conducting medium fills the gap between the accommodating groove and the heat pipe, so as to increase the contact between the heat pipe and the accommodating groove to have a better heat transfer effect. However, the means of providing the heat-conducting medium increases the difficulty of the manufacturing process, and the cost also increases accordingly. On the other hand, the gap problem can be improved, but the gap cannot be completely eliminated. This will lead to the phenomenon that the thickness of the heat-conducting medium is inconsistent. In addition, due to the large deformation of the heat pipe and the heat dissipation base plate, it is necessary to form two receiving grooves on the heat dissipation base plate. When the heat pipe is embedded by the mechanical riveting and flattening process, the raised rib is configured to fasten the heat pipe, and the receiving grooves are configured to receive the excess metal formed by the two raised ribs after the mechanical riveting and flattening process, so that the surface of the heat dissipation base plate can be kept flat. In this way, the fabrication of the heat dissipation base plate becomes more complicated. Moreover, because the deformation of the heat pipe and the heat dissipation base plate is larger, the thickness of the heat dissipation base plate needs to be designed thicker to withstand the pressure of riveting deformation. As a result, the overall structure is heavier. The inside of the heat dissipation structure in the same size has less space for accommodating the heat pipe. In this combination structure, as disclosed in the above-mentioned document, the receiving grooves may not be completely filled. The surface of the heat dissipation base plate can only form a substantially coplanar plane. Thus, the heat transfer effect is still limited. It is difficult to meet the requirements for less application space and a better heat transfer effect.

Therefore, it is necessary to study a new technical solution to solve the above problems.

### SUMMARY OF THE INVENTION

In view of the defects of the prior art, the primary object of the present invention is to provide a tight-fit riveting structure for a heat dissipation aluminum base and a heat pipe, which has the advantages of being lighter, thinner, and having a larger internal cavity space. Moreover, the heat dissipation aluminum base is suitable for heat pipes in any shape. The heat dissipation aluminum base is in a tight fit with the heat pipe, which is beneficial to improve the heat dissipation performance. The product is manufactured by pressing. The production process is simple. It is suitable for popularization and application.

In order to achieve the above object, the present invention adopts the following technical solutions.

A tight-fit riveting structure for a heat dissipation aluminum base and a heat pipe comprises a heat dissipation aluminum base, a heat pipe, and a holder. The heat pipe is riveted and clamped on the heat dissipation aluminum base. The holder is mounted to an underside of the heat dissipation aluminum base. When the heat dissipation aluminum base is to be manufactured, an upper surface of a thin aluminum plate is pressed downward to form an arched portion. The arched portion protrudes below the thin aluminum plate. A cavity is defined in the arched portion. The cavity has an upper end opening. The cavity has an inner width corresponding to an outer width of the heat pipe. The cavity has a depth greater than a thickness of the heat pipe. A bottom of the arched portion is shaped upward to form two raised portions respectively located on both sides of the upper end opening. The raised portions protrude upward from the upper surface of the thin aluminum plate. The raised portions each have a thickness less than that of the thin aluminum plate. The depth of the cavity after being shaped upward is equal to the thickness of the heat pipe.

The heat pipe is placed into the cavity from the upper end opening of the cavity, and then the raised portions on both sides of the upper end opening are pressed and deformed toward the heat pipe to be flush with the upper surface of the thin aluminum plate, so that outer surfaces of a bottom and two sides of the heat pipe are in close contact with the heat dissipation aluminum base, and tops of the two sides of the heat pipe are riveted and fixed.

Compared with the prior art, the present invention has obvious advantages and beneficial effects. Specifically, it can be seen from the above technical solutions that a thin aluminum plate is pressed downward to form an arched portion to obtain a cavity corresponding in shape and size to the heat pipe. The cavity has a depth greater than the thickness of the heat pipe. Then, the bottom of the arched portion is shaped upward to form two raised portions respectively located on both sides of the upper end opening. The thickness of the raised portion is less than the thickness of the thin aluminum plate. The depth of the cavity after being shaped upward is equal to the thickness of the heat pipe. Thus, after the heat pipe is placed into the cavity from the upper end opening of the cavity, the heat pipe is in a close contact with the inner wall of the cavity. The raised portions on both sides of the upper end opening are pressed and deformed toward the heat pipe to be flush with the upper surface of the thin aluminum plate, thereby strengthening the combination of the heat pipe and the heat dissipation aluminum base. Compared with the prior art, this heat dissipation aluminum base has the advantages of being lighter, thinner and having a larger internal cavity space, so as to meet the requirements for less application space. Moreover, the heat dissipation aluminum base is suitable for heat pipes in any shape. The heat dissipation aluminum base is in a close fit with the heat pipe, which is beneficial to improve the heat dissipation performance. The heat dissipation aluminum base is manufactured by pressing. The production process is simple. It is suitable for popularization and application.

### BRIEF DESCRIPTION OF THE DRAWINGS

FIG. 1 is a perspective view of a first embodiment of the present invention;

FIG. 2 is an exploded view of the first embodiment of the present invention;

FIG. 3 is a schematic view showing the manufacturing process of the first embodiment of the present invention;

FIG. 4 is a perspective view of a second embodiment of the present invention;

FIG. 5 is an exploded view of the second embodiment of the present invention;

FIG. 6 is a perspective view of a third embodiment of the present invention;

FIG. 7 is an exploded view of the third embodiment of the present invention;

FIG. 8 is a schematic view showing the manufacturing process of the third embodiment of the present invention;

FIG. 9 is a perspective view of a fourth embodiment of the present invention; and

FIG. 10 is an exploded view of the fourth embodiment of the present invention.

### DETAILED DESCRIPTION OF THE PREFERRED EMBODIMENTS

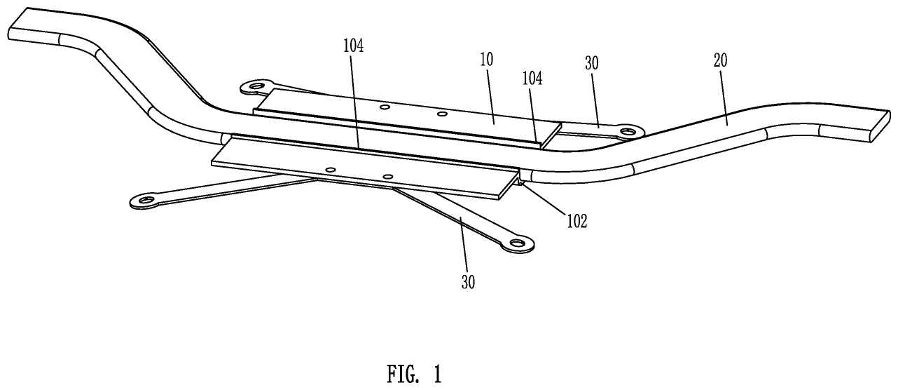

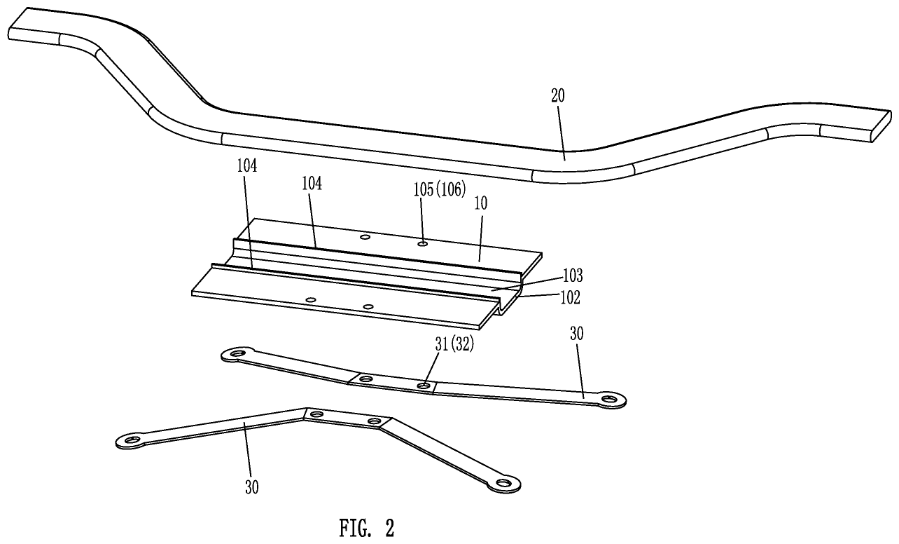

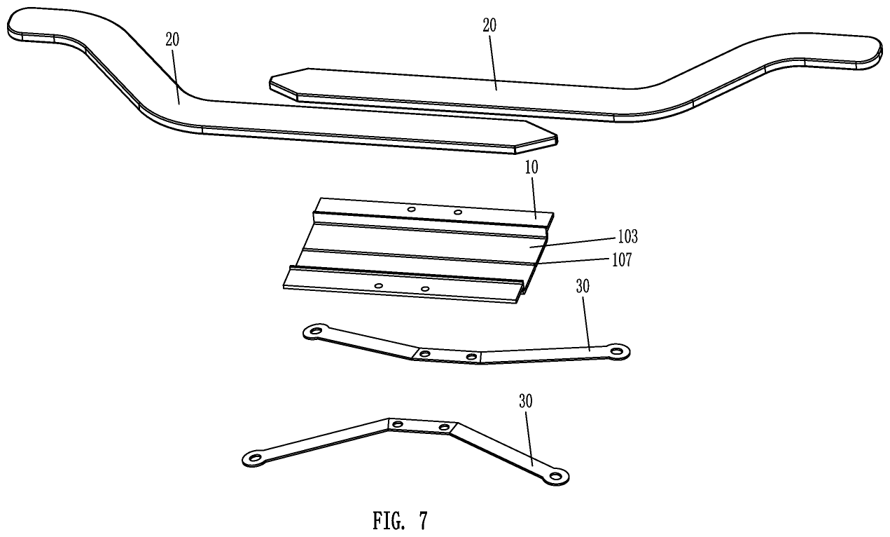

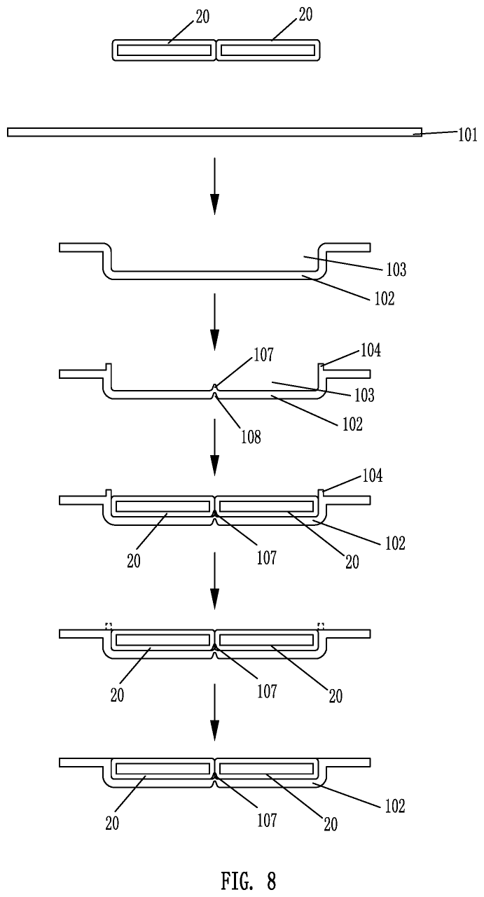

FIGS. 1 to 10 show the specific structures of various embodiments of the present invention.

Spatially relative terms, such as “upper,” “lower,” “front,” “rear,” “left,” “right,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures.

FIGS. 1 to 3 show the specific structure of a first embodiment of the present invention.

A tight-fit riveting structure for a heat dissipation aluminum base and a heat pipe, comprising a heat dissipation aluminum base 10, a heat pipe 20 and a holder 30. The heat pipe 20 is clamped and fixed on the heat dissipation aluminum base 10. The holder 30 is mounted to the underside of the heat dissipation aluminum base 10.

The manufacture and the riveting assembly of the heat dissipation aluminum base 10, the heat pipe 20 and the holder 30 includes the following steps:

Step 1. Preparing the heat dissipation aluminum base 10 and the heat pipe 20, wherein, the heat pipe 20 includes one heat pipe. The heat pipe 20 is flat and thin, having a thickness less than a width between its left and right end faces. The upper and lower end faces of the heat pipe 20 are flat faces. The left and right end faces of the heat pipe 20 are curved faces (convex curved faces).

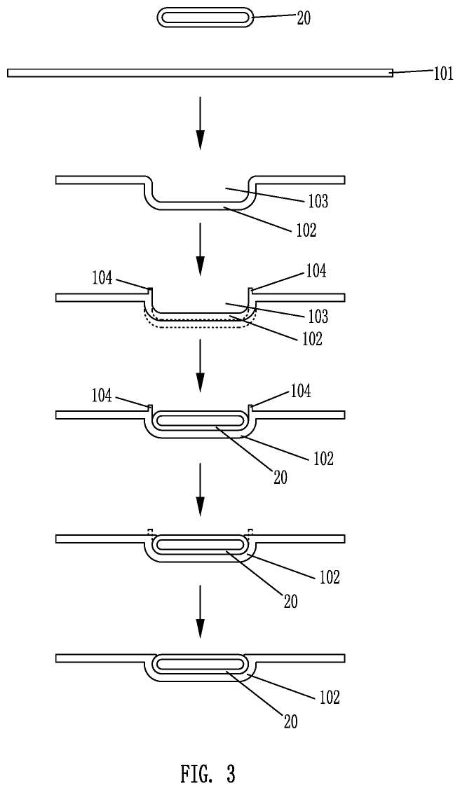

As shown in FIG. 3, when the heat dissipation aluminum base 10 is to be manufactured, a thin aluminum plate 101 is first prepared. The upper surface of the thin aluminum plate 101 is pressed downward to form an arched portion 102. The arched portion 102 protrudes below the thin aluminum plate 101. A cavity 103 is defined in the arched portion 102. The cavity 103 of the heat dissipation aluminum base 10 is a straight cavity. The cavity 103 has an upper end opening. The inner width of the cavity 103 corresponds to the outer width of the heat pipe 20. The depth of the cavity 103 is greater than the thickness of the heat pipe 20. Then, the bottom of the arched portion 102 is shaped upward to form two raised portions 104 respectively located on both sides of the upper end opening. The raised portions 104 protrude upward from the upper surface of the thin aluminum plate 101. The thickness of the raised portion 104 is less than the thickness of the thin aluminum plate 101. The depth of the cavity 103 after being shaped upward is equal to the thickness of the heat pipe 20.

Step 2. The heat pipe 20 is placed into the cavity 103 from the upper end opening of the cavity 103, and then the raised portions 104 on both sides of the upper end opening are pressed and deformed toward the heat pipe 20 to be flush with the upper surface of the thin aluminum plate 101, so that the outer surfaces of the bottom and the two sides of the heat pipe 20 are tightly attached to the heat dissipation aluminum base 10, and the tops of the two sides of the heat pipe 20 are riveted and fixed.

Step 3. The holder 30 is mounted to the underside of the heat dissipation aluminum base 10. The left and right sides of the heat dissipation aluminum base 10, corresponding to of the bottom of the cavity 103, have holder mounting portions 11, respectively. The holder 30 includes two holders to be respectively mounted to the undersides of the holder mounting portions 11 of the left and right sides of the heat dissipation aluminum base 10. The holder 30 has a first connection hole 31. The upper surface of the holder mounting portion 11 is pressed downward to form a first protrusion 105. The first protrusion 105 protrudes below the holder mounting portion 11. The first protrusion 105 passes through the first connection hole 31. The bottom of the first protrusion 105 is riveted and positioned to the bottom of the holder 30. The holder 30 may be locked to the holder mounting portion 11 with a screw. For example, the holder 30 has a second connection hole 32. The holder mounting portion 11 has a third connection hole 106. The second connection hole 32 and the third connection hole 106 are locked by a screw.

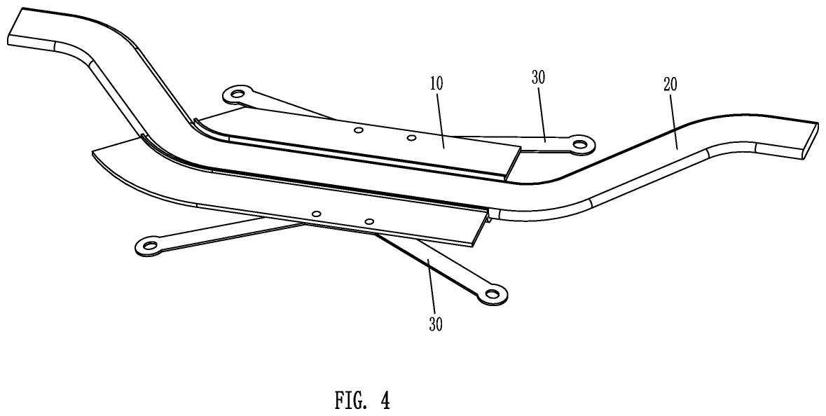

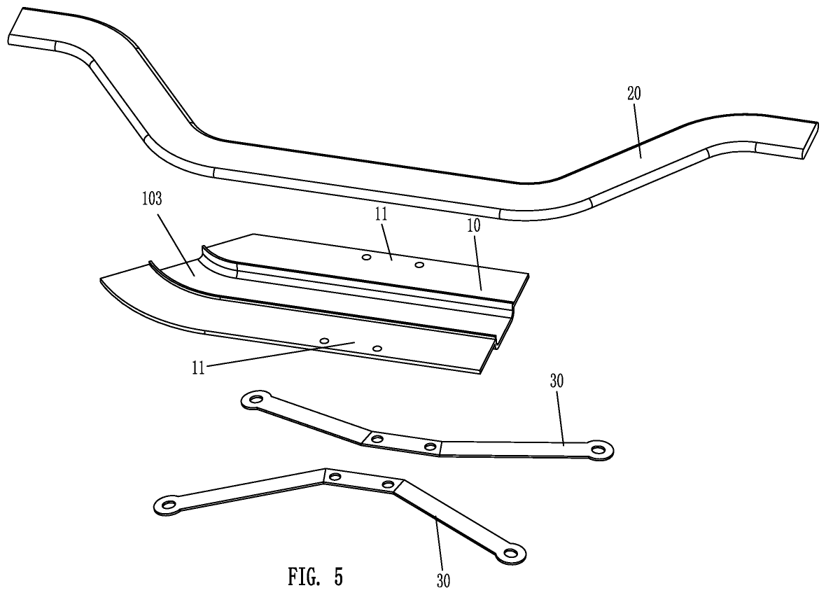

FIGS. 4 to 5 show the specific structure of a second embodiment of the present invention. The second embodiment is substantially similar to the first embodiment with the exceptions described hereinafter. The cavity 103 of the heat dissipation aluminum base 10 is a special-shaped cavity, not a straight cavity.

Because the heat dissipation aluminum base 10 is made by pressing a thin aluminum plate 101, the shape of the cavity 103 can be arbitrarily designed, so it can be suitable for any shape of the heat pipe 20.

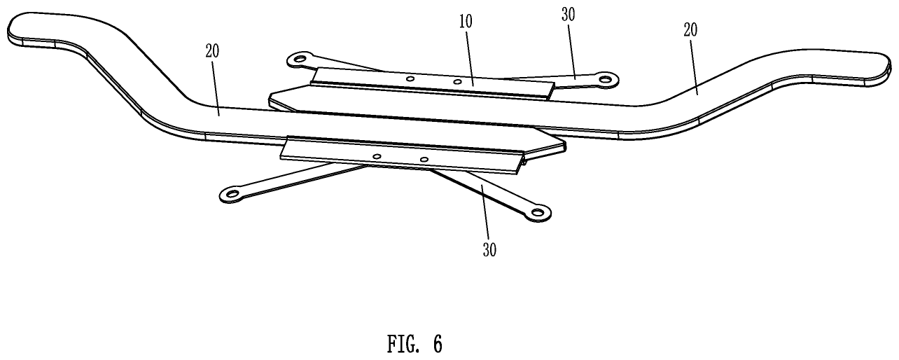

FIGS. 6 to 8 show the specific structure of a third embodiment of the present invention. The third embodiment is substantially similar to the first embodiment with the exceptions described hereinafter. The heat pipe 20 includes two heat pipes (or more than two heat pipes). All the heat pipes 20 are arranged side by side in the cavity 103. When the bottom of the arched portion 102 is shaped upward, a second protrusion 107 is formed. The second protrusion 107 extends upward from the inner bottom surface of the cavity 103. The second protrusion 107 is gradually reduced upward. The bottom of the arched portion 102 is formed with a recess 108 aligned with the bottom of the second protrusion 107. The second protrusion 107 is located between the adjacent heat pipes 20 to separate the adjacent heat pipes 20. Both sides of the second protrusion 107 are concave arc surfaces, which are matched with the convex arc outer surfaces of both sides close to the bottom of the heat pipe 20. The second protrusion 107 plays a better role in positioning the adjacent heat pipes 20, and also improves the contact tightness and increase the contact area between the heat pipes 20 and the heat dissipation aluminum base 10.

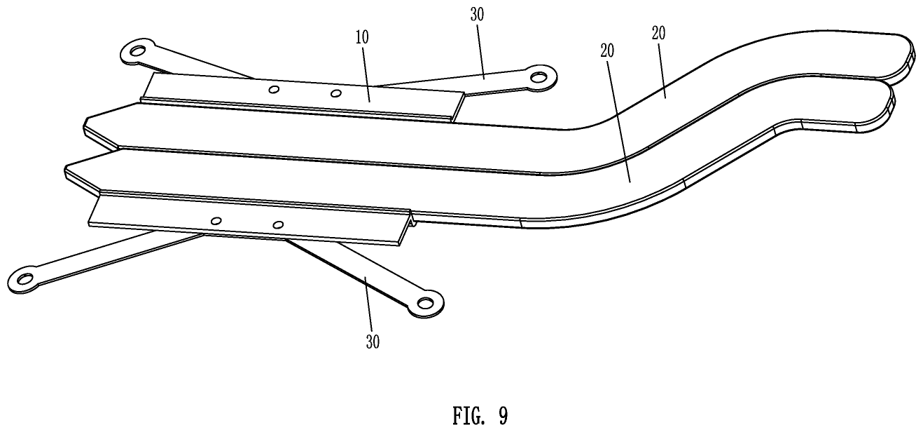

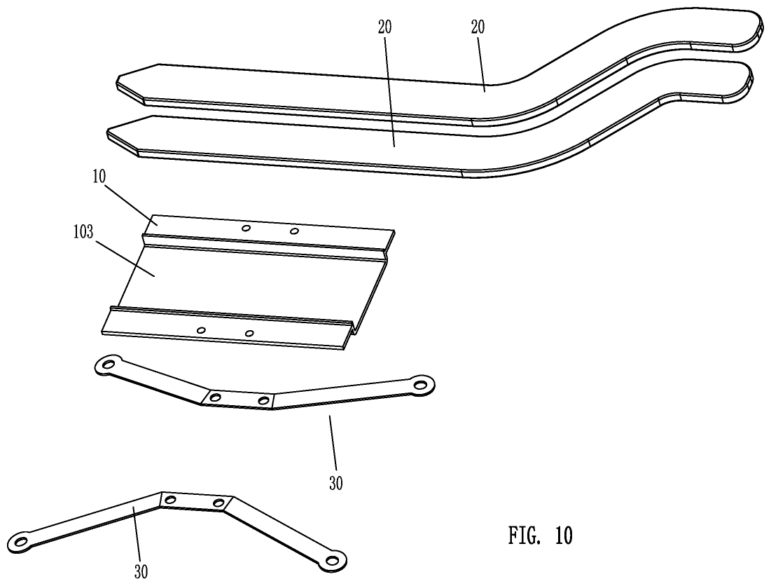

FIGS. 9 to 10 show the specific structure of a fourth embodiment of the present invention. The fourth embodiment is substantially similar to the first embodiment with the exceptions described hereinafter. The heat pipe 20 includes two heat pipes (or more than two heat pipes). All the heat pipes 20 are arranged side by side in the cavity 103.

What is claimed is:

1. A tight-fit riveting structure for a heat dissipation aluminum base and a heat pipe, comprising a heat dissipation aluminum base, a heat pipe and a holder, the heat pipe being riveted and clamped on the heat dissipation aluminum base, the holder being mounted to an underside of the heat dissipation aluminum base;
wherein when the heat dissipation aluminum base is to be manufactured, an upper surface of a thin aluminum plate is pressed downward to form an arched portion, the arched portion protrudes below the thin aluminum plate, a cavity is defined in the arched portion, the cavity has an upper end opening, the cavity has an inner width corresponding to an outer width of the heat pipe, the cavity has a depth greater than a thickness of the heat pipe, a bottom of the arched portion is shaped upward to form two raised portions respectively located on both sides of the upper end opening, the raised portions protrude upward from the upper surface of the thin aluminum plate, the raised portions each have a thickness less than that of the thin aluminum plate, the depth of the cavity after being shaped upward is equal to the thickness of the heat pipe;
wherein the heat pipe is placed into the cavity from the upper end opening of the cavity, and then the raised portions on both sides of the upper end opening are pressed and deformed toward the heat pipe to be flush with the upper surface of the thin aluminum plate, so that outer surface of a bottom and two sides of the heat pipe are tightly attached to the heat dissipation aluminum base, and tops of the two sides of the heat pipe are riveted and fixed.

2. The tight-fit riveting structure as claimed in claim 1, wherein the heat pipe is flat and thin, and the thickness of the heat pipe is less than a width between its left and right end faces.

3. The tight-fit riveting structure as claimed in claim 2, wherein upper and lower end faces of the heat pipe are flat faces, and the left and right end faces of the heat pipe are curved faces.

4. The tight-fit riveting structure as claimed in claim 1, wherein left and right sides of the heat dissipation aluminum base, corresponding to a bottom of the cavity, have respective holder mounting portions, and the holder includes two holders to be respectively mounted to undersides of the holder mounting portions of the left and right sides of the heat dissipation aluminum base.

5. The tight-fit riveting structure as claimed in claim 1, wherein the heat pipe includes one heat pipe.

6. The tight-fit riveting structure as claimed in claim 1, wherein the heat pipe includes at least two heat pipes, and the heat pipes are arranged side by side in the cavity.

7. The tight-fit riveting structure as claimed in claim 6, wherein when the bottom of the arched portion is shaped upward, a second protrusion is formed, the second protrusion extends upward from an inner bottom surface of the cavity, the second protrusion is gradually reduced upward, the bottom of the arched portion is formed with a recess aligned with a bottom of the second protrusion; and the second protrusion is located between the adjacent heat pipes to separate the adjacent heat pipes.
